(19) United States
(12) Patent Application Publication
(10) Pub. No.: US 2005/0042531 A1
(43) Pub. Date: Feb. 24, 2005

(54) Film for plasma display filter and plasma display filter comprising the same

(76) Inventors: Yeon-Keun Lee, Daejeon-city (KR); Sang-Hyun Park, Daejeon-city (KR); Jung-Doo Kim, Daejeon-city (KR); Hyun-Seok Choi, Seoul (KR); In-Seok Hwang, Daejeon-city (KR); Dong-Wook Lee, Busan-city (KR)

Correspondence Address: CANTOR COLBURN LLP, 55 Griffin Road South, Bloomfield, CT, 06002, US

(21) Appl. No.: 10/920,627

(22) Filed: Aug. 18, 2004

(30) Foreign Application Priority Data
Aug. 19, 2003 (KR) 10-2003-0057206
Jul. 9, 2004 (KR) 10-2004-0053382

(51) Int. Cl. G03F 9/00

(52) U.S. Cl. 430/7

(57) ABSTRACT

Disclosed is a film for a plasma display filter comprising a binder resin selected from the group consisting of a polyvinyl chloride resin (PVC), a chlorinated polyvinyl chloride resin (CPVC), and a mixture thereof; and a dye selected from the group consisting of a near IR absorbing dye, a neon-cut dye, a color control dye and mixtures thereof, which enables integration of a near IR absorbing film and a neon-cut film, experiences less transmittance change at high temperature and humidity, has superior durability and thermal stability, and has a high transmittance in the visible region, and a plasma display filter comprising the same.

### BACKGROUND OF THE INVENTION

(a) Field of the Invention

The present invention relates to a film for a plasma display filter and a plasma display filter comprising the same, and more particularly to a film for a plasma display filter comprising a binder resin comprising a polyvinyl chloride resin or a chlorinated polyvinyl chloride resin and a dye selected from the group consisting of a near IR (infrared) absorbing dye, a neon-cut dye, and a color control dye, which enables integration of a near IR absorbing film and a neon-cut film, experiences less transmittance change at high temperature and humidity, has superior durability and thermal stability, and offers high transmittance in the visible region, and a plasma display filter comprising the same.

(b) Description of the Related Art

Of late, a plasma display panel (PDP) has been gaining focus as a flat panel display for offering a large screen.

The plasma display panel offers the three primary colors by sealing in a discharge gas such as neon (Ne), argon (Ar), xenon (Xe), etc. and emitting each light of red, green, and blue phosphors by vacuum UV (ultraviolet). However, it is difficult to obtain a clear red color because a neon orange light is emitted at around 590 nm as the excited neon atom returns to the ground state.

To solve this problem, an additional plasma display filter is employed in the plasma display panel, so that the visible rays of red (R), green (G), and blue (B) pass through the filter and the orange light around 590 nm and the near IR in the region of 800 to 1000 nm are blocked.

FIG. 1 is a perspective view of the conventional plasma display device.

Referring to FIG. 1, the plasma display comprises a case 11 displaying an image, a driving circuit board 12 positioned at the back of the case 11 and equipped with electronic components for driving the panel, a panel assembly 13 offering red, green, and blue colors, a plasma display filter 14 positioned at the front of the assembly 13, and a cover 15 enclosing the case 11, the driving circuit board 12, the panel assembly 13, and the plasma display filter 14.

FIG. 2 is an enlarged cross-sectional view of the plasma display filter 14 of FIG. 1. The plasma display filter comprises several functional films stacked on a transparent plate.

Referring to FIG. 2, the plasma display filter 14 has a structure of an electromagnetic interference shielding film (EMI film) 142, a neon-cut film 144, a near IR absorbing film (NIR film) 146, and an anti-reflection film (AR film) 148 sequentially stacked on the transparent plate 140. Especially, the near IR absorbing film 146 has a structure comprising a near IR absorbing film in which a polymer resin comprising a near IR absorbing dye is coated on a transparent substrate.

Each of the near IR absorbing film 146 and the neon-cut film 144 has a structure of a near IR absorbing dye and a neon-cut dye added to the polymer resin as a color control dye coated on the transparent substrate, respectively.

The near IR absorbing film (NIR film) should have good durability at high temperature and humidity, and a high absorption rate in the near IR region of 800 to 1200 nm, especially from 850 to 1000 nm. Preferably, it has a transmittance of at least 60% for visible rays in the region of 430 to 700 nm. Especially, since a dye coating comprising a near IR absorbing dye is known to have poorer durability than a color control film comprising a neon-cut dye and a color control dye improvement of durability is imminent.

The durability of the near IR absorbing film is determined by the transmittance change before and after exposing the film to high temperature and humidity for a given time. The smaller the transmittance change, the more durable the film is. The durability depends not only on the dye itself but also on the kind of binder resin used for making the film.

The near IR absorbing film is prepared by coating a mixture solution of the dye and the binder on the transparent plate, or heating it into a film.

The binder used are polycarbonates, aliphatic polyesters, polyacryls, melamines, urethanes, aromatic esters, aliphatic polyolefins, aromatic polyolefins, polyvinyls, polyvinyl alcohols, poly(methyl methacrylate)s, polystyrenes, and copolymers thereof.

For the dye, an ammonium salt, an aminium salt, a diimmonium salt, quinone, phthalocyanine, naphthalocyanine, cyanine, or a metal complex dye is used, as disclosed in U.S. Pat. No. 5,804,102 and U.S. Patent Publication No. 2001-0005278.

Among these, phthalocyanine, naphthalocyanine, cyanine, or dithiol metal complex dyes are widely used because they have superior thermal stability against heat generated during driving of the plasma display panel. However, because these dyes have sharp near IR absorption peaks, they cannot absorb light in the wide near IR region, and the amount of dye should be increased to absorb light in the wide near IR region. Considering the high price of the dye, this increase production cost. And, the cyanine dye has poor durability under high temperature and humidity.

On the contrary, the ammonium salt, aminium salt, immonium salt, or diimmonium salt dyes have near broad IR absorption peaks and superior visible transmittance, and are less expensive than the above dyes. However, the salt dyes also have poor near IR absorption capabilities and experiences transmittance change in the visible region when exposed to high temperature or humidity for a long time. Moreover, they have poor thermal stability.

U.S. Pat. Nos. 6,117,370 and 6,522,463 disclose a near IR absorbing film prepared by using a polycarbonate resin, a polyacrylate resin or a polyester resin in which at least 60 mol % of the dicylclic diol components have been copolymerized as binder resin, mixing a diimmonium or dithiol nickel complex dye with trichloromethane (CHCl₃) and coating it on a transparent substrate. However, the use of chloroform (CHCl₃) is internationally regulated because it is known to destroy the ozone layer. Therefore, an additional system to collect the remaining chloroform should be equipped.

Accordingly, with the recently increasing interest in plasma display panels, development of a plasma display filter having superior durability and stable physical properties including transmittance even at high temperature and humidity is imminent.

### SUMMARY OF THE INVENTION

It is an object of the present invention to provide a film for a plasma display filter experiencing less transmittance change and having superior durability and thermal stability and high transmittance in the visible region at high temperature and humidity.

It is another object of the present invention to provide a film for a plasma display filter enabling integration of a near IR absorbing film and a neon-cut film.

It is still another object of the present invention to provide a plasma display filter comprising the film for a plasma display filter.

### BRIEF DESCRIPTION OF THE DRAWINGS

FIG. 1 is a perspective view of the conventional plasma display device.

FIG. 2 is an enlarged cross-sectional view of the plasma display filter of FIG. 1.

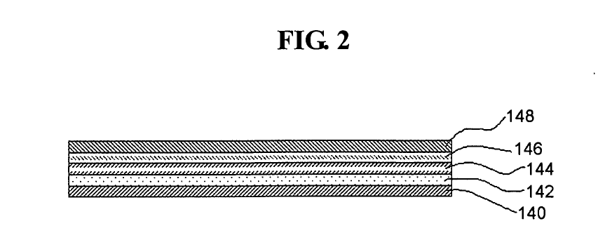

FIG. 3a is a graph showing the transmittance change of the film for a plasma display filter prepared in Example 2.

FIG. 3b is a graph showing the transmittance change of the film for a plasma display filter prepared in Example 3.

FIG. 4a is a graph showing the transmittance change of the film for a plasma display filter prepared in Comparative Example 1.

FIG. 4b is a graph showing the transmittance change of the film for a plasma display filter prepared in Comparative Example 2.

### DETAILED DESCRIPTION OF THE PREFERRED EMBODIMENTS

The present invention provides a film for a plasma display filter comprising

(a) a binder resin selected from the group consisting of a polyvinyl chloride resin (PVC), a chlorinated polyvinyl chloride resin (CPVC), and a mixture thereof; and

(b) a dye selected from the group consisting of a near IR absorbing dye, a neon-cut dye, a color control dye, and mixtures thereof.

The present invention also provides a plasma display filter comprising the film for a plasma display filter.

Hereunder a more detailed description of the present invention is given.

The present inventors found that when a near IR absorbing film and a neon-cut film are prepared using a polyvinyl chloride resin, a chlorinated polyvinyl chloride resin, or a mixture thereof as a binder resin, the resultant film for a plasma display filter has superior durability at high temperature and humidity with less transmittance change, and that when a film is prepared by using the polyvinyl chloride resin, the chlorinated polyvinyl chloride resin, or a mixture thereof as a binder resin and mixing it with a near IR absorbing dye, a neon-cut dye, a color control dye, or mixture thereof, integration of a near IR absorbing film and a neon-cut film becomes possible, so that the manufacture of a plasma display filter becomes easy and a thin plasma display filter can be obtained.

A near IR absorbing film should be required high durability and excellent transmittance and the “durability” of near IR absorbing film depends on binder resins.

While the binder resin affects the durability, a near IR absorbing dye has impact on the absorption spectrum of the near IR absorbing film. For the near IR absorbing dye, it is widely used ammonium salt, immonium salt, diimmonium salt, quinine, phthalocyanine, naphthalocyanine, cyanine, metal complex and etc.

The dye such as phthalocyanine, naphthalocyanine and cyanine complex has so narrow and sharp absorbing spectrum (about 850 nm), even though high durability, that there is a limitation to absorption of near IR spectrum emitted from plasma display panel.

Also, the diimmonium salt dye has disadvantages of decreasing durability and changing transmittance at high temperature and/or high humidity, although it has a broad near IR absorbing spectrum (900˜1200 nm) in the near infrared region. For the IR absorbing dye, therefore, it is necessary to be used with the binder which enables to improve durability.

Preferably, it is suggested that the combination metal complex, phthalocyanine or cyanine and diimmonium salt can absorb the wide wavelength of near IR region ranging from 850 to 1200 nm, which is emitted from plasma display panel.

Various binder resins have been developed to improve durability. Especially, it was found polycarbonate resin increased the durability of diimmonium salt dye. However, a near IR absorbing film including polycarbonate resin should be positively necessary the usage of chloroform (CHCl₃) as a solvent, which makes usable solvent set limit to. Besides, to use chloroform in a manufacturing process of the IR near absorbing film should be required a recovery system necessarily, as controlled internationally owing to destroy ozone layer.

The present invention replaces the conventional binder resin with a polyvinyl chloride resin, a chlorinated polyvinyl chloride resin, or a mixture thereof to improve durability of the film for a plasma display filter. Preferably, for the chlorinated polyvinyl chloride resin, one having a degree of chlorination ranging from 60 to 68%, which has better heat resistance, weather resistance, corrosion resistance, chemical resistance, creep resistance, flame resistance, and dimensional stability than the conventional polyvinyl chloride resin is used.

And, in the present invention, a diimmonium salt dye is used as a major near IR absorbing dye. It is also possible to use a metal complex, phthalocyanine, or cyanine dye as a supplementary near IR absorbing dye to absorb near IR at around 850 nm, which the absorbing wavelength is beyond diimmonium salt dye.

For the dye, any of the commonly used ammonium salt, aminium salt, immonium salt, diimmonium salt, quinone, phthalocyanine, naphthalocyanine, cyanine, or metal complex dyes can be used. Among these, diimmonium salt dye is preferable.

Preferably, the diimmonium ion of the diimmonium salt is represented by Formula 1 below: 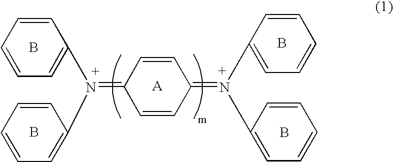
where

m is an integer of 1 or 2;

the two quaternary nitrogen atoms bonded to the ring A are bonded to four phenyl groups B; and

the phenyl groups B have four substituted amino groups at the 4-positions.

Preferably, a monovalent or divalent organic acid anion or a monovalent or divalent inorganic acid anion binds with the diimmonium ion. For the monovalent organic acid anion, one selected from the group consisting of an organic carboxylate ion, such as acetate, lactate, trifluoroacetate, propionate, benzoate, oxalate, succinate, and stearate; an organic sulfonate ion, such as metal sulfonate, toluenesulfonate, naphthalenemonosulfonate, chlorobenzenesulfonate, nitrobenzenesulfonate, dodecylbenzenesulfonate, benzoin sulfonate, ethanesulfonate, and trifluoromethanesulfonate; and an organic borate ion, such as tetraphenylborate and butyltriphenylborate is preferably used.

For the organic acid divalent anion, one selected from the group consisting of naphthalene-1,5-disulfonate, naphthalene-1,6-disulfonate, and naphthalene disulfonate derivatives is preferably used.

For the monovalent inorganic acid anion, one selected from the group consisting of a halogenite such as fluoride, chloride, bromide, and iodide, thiocyanate, hexafluoroantimonate, perchlorate, periodate, nitrate, tetrafluoroborate, hexafluorophosphate, molybdate, tungstate, titanate, vanadate, phosphate, and borate is preferably used.

Preferably, the diimmonium salt having a diimmonium ion represented by Formula 1 is the compound represented by Formula 2 below. 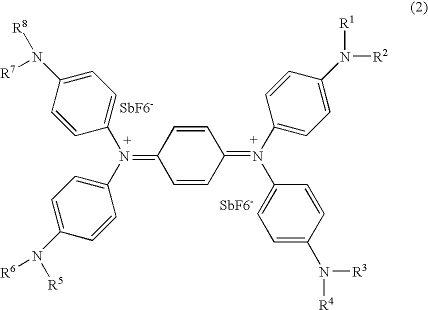
where

each of R¹ to R⁸ is a group selected from the group consisting of hydrogen, an alkyl group having 1 to 5 carbon atoms, and an aryl group having 3 to 5 carbon atoms, identically or differently.

Preferably, each of the R¹ to R⁸ is a butyl group.

Preferably, the weight proportion of (a) the binder resin and (b) the dye ranges from 5:1 to 200:1. If the content of the binder resin is below 5 parts by weight per 1 part by weight of the dye, improvement of the durability of the film cannot be expected. And, if the content of the binder resin exceeds 200 parts by weight per 1 part by weight of the dye, the coating film becomes too thick, so that the drying time increases and the coating surface becomes non-uniform.

The plasma display film of the present invention can be prepared by dissolving a polyvinyl chloride resin, a chlorinated polyvinyl chloride resin or a mixture thereof to prepare a binder solution, and mixing a near IR absorbing dye, a neon-cut dye, a color control dye, or mixtures thereof to the solution. The resultant film acts both as a near IR absorbing film and a neon-cut film at the same time.

For the neon-cut dye, any commonly used neon-cut dye can be used. Especially, a cyanine, squarylium, or azo-metal dye is preferable. And, for the color control dye, any commonly used color control dye can be used. Especially, an anthraquinone, phthalocyanine or thioindigo dye is preferable.

The film for a plasma display filter of the present invention may also be prepared by the known methods. For example, a binder resin is dissolved in an organic solvent to prepare a binder solution and a dye is added to the binder solution. Then, the resultant solution is coated on a substrate and dried. The coating may be performed by spray coating, roll coating, bar coating, spin coating, etc. For the solvent, any commonly used organic solvent, preferably methyl ethyl ketone (MEK) or tetrahydrofuran (THF), may be used.

When preparing the conventional film for a plasma display filter, chloroform, which is a main cause of environmental pollution, is used as solvent. But, in the present invention, any commonly used organic solvent may be used, and therefore it is unnecessary to introduce a special solvent collecting system. As a result, the film preparation process becomes simple and it is possible to reduce the production cost.

As described above, the film for a plasma display filter of the present invention comprises a polyvinyl chloride resin or a chlorinated polyvinyl chloride resin as a binder resin, so that it is highly durable at high temperature and humidity with less transmittance change, is thermally stable, and has a high transmittance in the visible region. And, because the commonly used organic solvent can be used, preparation of the film becomes easy. Also, because the film can be prepared by adding a near IR absorbing dye, a neon-cut dye, and a color control dye at the same time, integration of a near IR absorbing film and a neon-cut film is possible.

The present invention also provides a plasma display filter further comprising an anti-reflection film (AR film), an electromagnetic interference shielding film (EMI film), and a black screen treatment film in addition to the above-mentioned film for a plasma display filter.

The plasma display filter not only absorbs near IR, but also protects the panel, prevents reflection, improves color control and color balance, improves contrast, blocks electromagnetic interference and blocks the orange neon light, which is generated during plasma discharge.

The present invention also provides a plasma display panel comprising the plasma display filter.

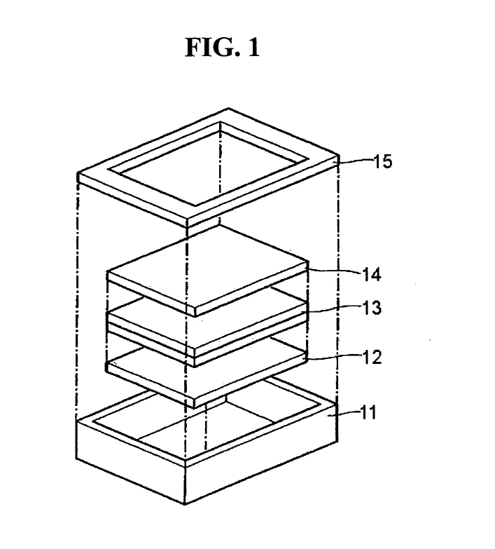

The plasma display panel of the present invention is prepared by attaching a film prepared by using a polyvinyl chloride resin, a chlorinated polyvinyl chloride resin, etc. with good chemical resistance, etc. as a binder resin on the panel assembly of FIG. 1. The superior chemical resistance, etc. of the polyvinyl chloride resin, the chlorinated polyvinyl chloride resin, etc. reduces transmittance change at high temperature and humidity and offers superior thermal stability. Also, because the film has a high transmittance in the visible region, it is preferable to be used in a plasma display panel.

Hereinafter, the present invention is described in more detail through examples. However, the following examples are only for the understanding of the present invention and they do not limit the present invention.

### EXAMPLES

### Example 1

20 g of polyvinyl chloride resin was dissolved in 80 g of THF to prepare a 20% binder solution. 0.5 g of a diimmonium salt dye was added to the binder solution. The mixture was stirred to obtain a mixture solution. The mixture solution was coated on a dried transparent substrate to a thickness of 8 μm using a coater to obtain a dye coating. The dye coating was dried at 80 to 120° C. for 5 minutes to obtain a near IR absorbing film. For the polyvinyl chloride resin, one having a degree of chlorination of 56.8% was used.

### Example 2

The procedure of Example 1 was carried out, except for using a chlorinated polyvinyl chloride resin as a binder resin and using 0.5 g of a diimmonium salt dye and 0.3 g of a metal complex (dithiol based nickel complex) dye as a dye. For the chlorinated polyvinyl chloride resin, one having a degree of chlorination of 64% was used.

### Example 3

The procedure of Example 1 was carried out, except for using a chlorinated polyvinyl chloride resin as a binder resin and using 0.5 g of a diimmonium salt dye, 0.3 g of a metal complex (dithiol based nickel complex) dye, 0.05 g of a neon-cut dye ( squarylium), and 0.05 g of a color control dye (anthraquinone dye) as a dye. As a result, a film in which a near IR absorbing film and a neon-cut film were integrated was obtained. For the chlorinated polyvinyl chloride resin, one having a degree of chlorination of 64.0% was used.

### Comparative Example 1

A near IR absorbing film was prepared as in Example 1, except for using poly(methyl methacrylate) as a binder resin.

### Comparative Example 2

A near IR absorbing film was prepared as in Example 3, except for using poly(methyl methacrylate) as a binder resin.

### Testing Example 1

Durability Test

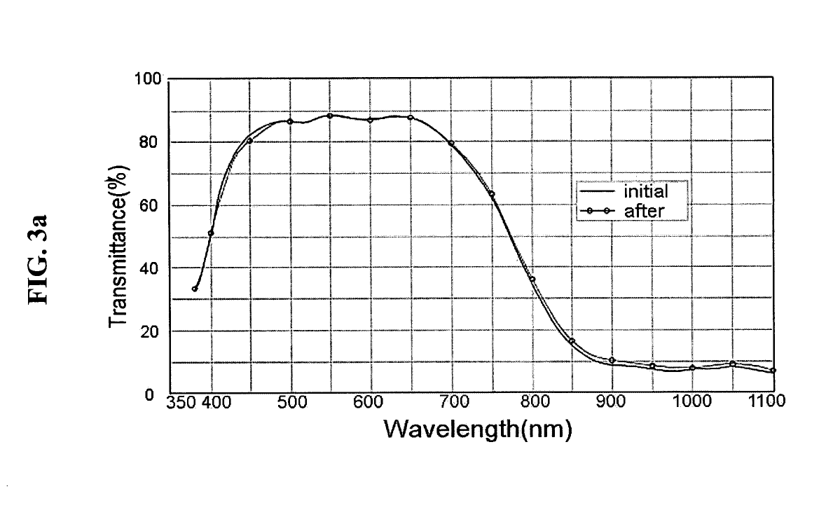

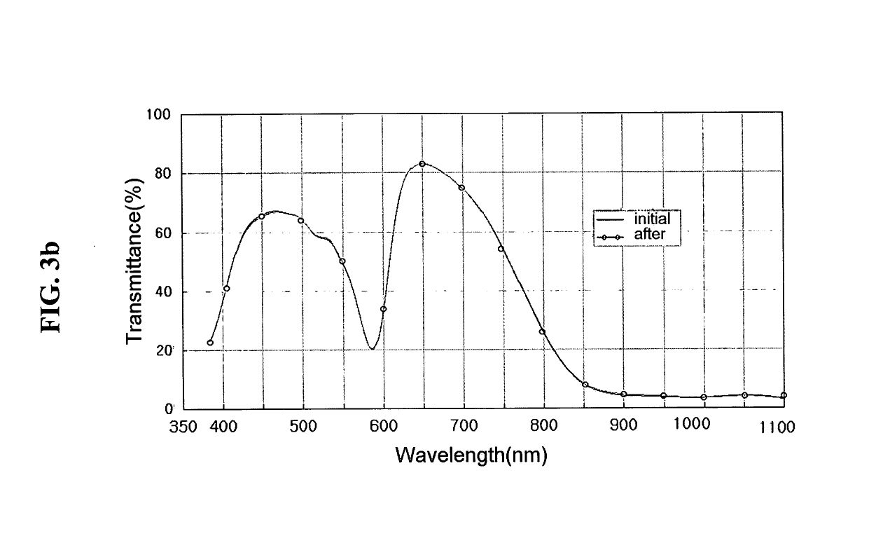

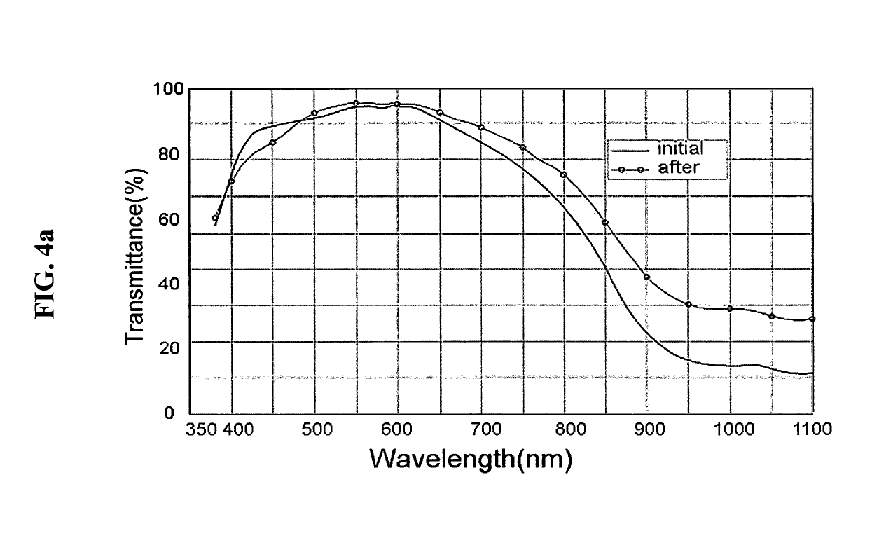

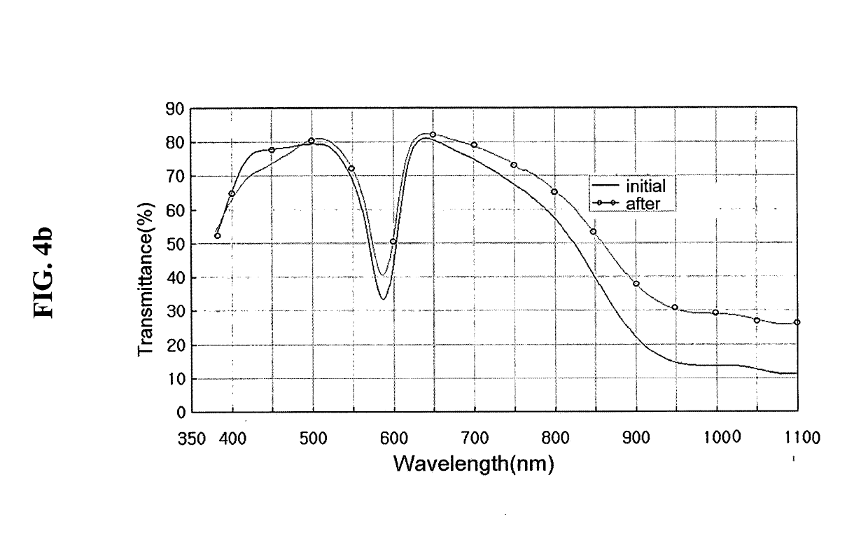

For each dye coating film (near IR absorbing film) prepared in Examples 1 to 3 and Comparative Examples 1 and 2, near IR and visible transmission spectrums were examined before and after keeping them at 80° C. for 500 hours. The results are given in Table 1 below, and in FIGS. 3a to 4b.

TABLE 1

| | | | | | | | | | Near IR | |
|---|---|---|---|---|---|---|---|---|---|---|
| | | Visible region (nm) | | | | | | | region (nm) | |
| Classification | | 400 | 450 | 500 | 550 | 586 | 612 | 628 | 850 | 950 |
| Example 1 | Initial (%) | 65.3 | 86.8 | 90.0 | 93.1 | 94.1 | 94.5 | 94.4 | 49.9 | 11.6 |
| | After 500 | 65.0 | 84.7 | 89.9 | 92.9 | 93.8 | 94.2 | 94.1 | 50.8 | 12.4 |
| | hours | | | | | | | | | |
| | Change | −0.3 | −2.1 | −0.1 | −0.2 | −0.3 | −0.3 | −0.3 | +0.9 | +0.8 |
| | (%) | | | | | | | | | |
| Example 2 | Initial (%) | 49.2 | 80.5 | 87.2 | 88.3 | 87.3 | 87.7 | 88.2 | 15.0 | 7.6 |
| | After 500 | 49.1 | 79.3 | 87.0 | 88.1 | 87.1 | 87.4 | 88.0 | 16.1 | 8.7 |
| | hours (%) | | | | | | | | | |
| | Change | −0.1 | −1.2 | −0.2 | −0.2 | −0.2 | −0.3 | −0.2 | +1.1 | +1.1 |
| | (%) | | | | | | | | | |
| Example 3 | Initial (%) | 39.7 | 68.5 | 59.0 | 51.5 | 23.7 | 60.3 | 79.2 | 9.7 | 4.2 |
| | After 500 | 39.4 | 67.1 | 59.7 | 52.1 | 24.3 | 60.1 | 78.7 | 10.5 | 4.8 |
| | hours (%) | | | | | | | | | |
| | Change | −0.3 | −1.4 | +0.7 | +0.6 | +0.6 | −0.2 | −0.5 | +0.8 | +0.6 |
| | (%) | | | | | | | | | |
| Comparative | Initial (%) | 65.9 | 79.3 | 83.4 | 84.6 | 84.5 | 84.6 | 83.7 | 39.8 | 14.5 |
| Example 1 | After 500 | 64.3 | 75.4 | 84.7 | 85.4 | 85.3 | 85.2 | 85.5 | 52.8 | 30.3 |
| | hours (%) | | | | | | | | | |
| | Change | −1.6 | −3.9 | +1.3 | +0.8 | +0.8 | +0.6 | −0.8 | −13 | +15.8 |
| | (%) | | | | | | | | | |
| Comparative | Initial (%) | 64.6 | 77.9 | 77.5 | 69.3 | 33.9 | 63.3 | 78.9 | 40.1 | 14.5 |
| Example 2 | After 500 | 62.5 | 73.5 | 79.3 | 72.6 | 40.8 | 68.8 | 80.7 | 53.0 | 30.3 |
| | hours (%) | | | | | | | | | |
| | Change | −2.1 | −4.4 | +1.8 | +3.3 | +6.9 | +5.5 | +1.8 | +12.9 | +15.8 |
| | (%) | | | | | | | | | |

FIG. 3a is a graph showing the transmittance change of the film for a plasma display filter prepared in Example 2, and FIG. 3b is a graph showing that of Example 3.

FIG. 4a is a graph showing the transmittance change of the film for a plasma display filter prepared in Comparative Example 1 and FIG. 4b is that of Comparative Example 2.

The durability is determined by the transmittance change before and after exposing at high temperature and humidity for a given time. The smaller the transmittance change, the more durable the film is.

As seen in Table 1 and FIGS. 3a, 3b, 4a, and 4b, the films of Examples 1 to 3 experienced little transmittance change in the near IR region. On the other hand, those of Comparative Examples 1 and 2 experienced large transmittance change.

The film for a plasma display filter of the present invention, which comprises a polyvinyl chloride resin or a chlorinated polyvinyl chloride resin as a binder resin, has superior durability with less transmittance change at high temperature and humidity, has superior thermal stability, and has a high transmittance in the visible region. And, preparation of the film is easy because a commonly used organic solvent can be used. Also, because the film can be prepared by adding a near IR absorbing dye, a neon-cut dye, and a color control dye at the same time, integration of a near IR absorbing film and a neon-cut film is possible.

While the present invention has been described in detail with reference to the preferred embodiments, those skilled in the art will appreciate that various modifications and substitutions can be made thereto without departing form the spirit and scope of the present invention as set forth in the appended claims.

1. A film for a plasma display filter comprising:
(a) a binder resin selected from the group consisting of a polyvinyl chloride resin (PVC), a chlorinated polyvinyl chloride resin (CPVC), and a mixture thereof; and
(b) a dye selected from the group consisting of a near IR absorbing dye, a neon-cut dye, a color control dye, and mixtures thereof.

2. The film for a plasma display filter of claim 1, wherein the chlorinated polyvinyl chloride resin has a degree of chlorination ranging from 60 to 68%.

3. The film for a plasma display filter of claim 1, wherein (a) the binder resin and (b) the dye are comprised at 5:1 to 200:1 by weight.

4. The film for a plasma display filter of claim 1, wherein (b) the near IR absorbing dye is a dye selected from the group consisting of an ammonium salt, an aminium salt, an immonium salt, a diimmonium salt, quinone, phthalocyanine, naphthalocyanine, cyanine, a metal complex, and mixtures thereof.

5. The film for a plasma display filter of claim 4, wherein the diimmonium of the diimmonium salt dye is represented by Formula 1 below: 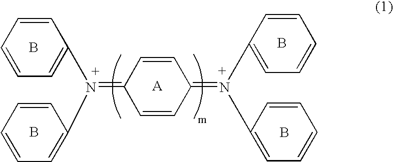
(where
m is an integer of 1 or 2;
the two quaternary nitrogen atoms bonded to the ring A are bonded to four phenyl groups B; and
the phenyl groups B have four substituted amino groups at the 4-positions.)

6. The film for a plasma display filter of claim 4, wherein the diimmonium salt dye is a compound represented by Formula 2 below: 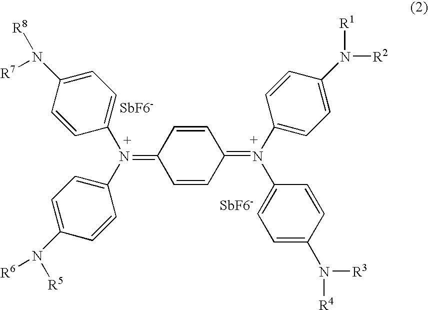
(where each of R¹ to R⁸ is a group selected from the group consisting of hydrogen, an alkyl group having 1 to 5 carbon atoms, and an aryl group having 3 to 5 carbon atoms, identically or differently.)

7. The film for a plasma display filter of claim 1, wherein a near IR absorbing film and a neon-cut film have been integrated.

8. A plasma display filter comprising the film of any one of claims 1 to 7.
